(19) United States
(12) Patent Application Publication
(10) Pub. No.: US 2014/0320156 A1
(43) Pub. Date: Oct. 30, 2014

(54) APPARATUS FOR DETECTING MISALIGNMENT OF TEST PAD

(71) Applicant: SK hynix Inc., Icheon-si Gyeonggi-do (KR)

(72) Inventor: Jong Su KIM, Icheon-si Gyeonggi-do (KR)

(73) Assignee: SK hynix Inc., Icheon-si Gyeonggi-do (KR)

(21) Appl. No.: 14/019,179

(22) Filed: Sep. 5, 2013

(30) Foreign Application Priority Data
Apr. 29, 2013 (KR) 10-2013-0047251

(51) Int. Cl. G01R 1/067

(52) U.S. Cl. CPC G01R 1/06794
USPC 324/750.24

(57) ABSTRACT

An apparatus for detecting misalignment of a test pad and a probe card includes: a test pad unit; a guard unit configured to surround the test pad unit, and formed to maintain a predetermined interval with the test pad unit; and a power supply unit configured to supply a predetermined voltage to the guard unit.

### CROSS-REFERENCES TO RELATED APPLICATION

The present application claims priority under 35 U.S.C. §119(a) to Korean application number 10-2013-0047251, filed on Apr. 29, 2013, in the Korean Intellectual Property Office, which is incorporated herein by reference in its entirety.

### BACKGROUND

1. Technical Field

Various embodiments generally relate to a semiconductor integrated circuit device, and more particularly, to an apparatus for detecting misalignment of a test pad.

2. Related Art

Recently, as semiconductor devices become highly integrated, the importance of inspection technology for inspecting the functions of semiconductor devices multiplexed according thereto has increased.

In general, the inspection of a semiconductor device is performed after a basic inspection of each unit process in the unit process has been performed, and the electrical inspection of an entire semiconductor chip is performed at a wafer level using a tester and a probe station after the semiconductor chip has been manufactured.

Such wafer level tests use different test schemes depending on the respective types and functions of semiconductors, and can be roughly classified into a disconnection and short test (i.e. open short test), a functional test, a current-voltage characteristic test using direct current (i.e. DC test), a speed test using alternating current (i.e. AC test), and the like.

Such a wafer level test functions to improve the overall process capability and yield by selecting and removing a semiconductor device having a defect and by solving a problem through a root cause analysis of the defect of the selected semiconductor device in the final step of a semiconductor manufacturing process

Such a wafer level test is a process of measuring the electrical characteristics of elements constituting a semiconductor chip, through the use of a needle of a probe card mounted on a probe station.

The needle of the probe card is contacted with a semiconductor chip, i.e. with a test pad electrically coupled to a pad which is formed on a scribe line of a wafer; an electric signal is applied through the needle; and then whether or not the semiconductor chip includes a fault, i.e. the electrical characteristics of elements constituting the semiconductor chip, are determined according to a signal checked from the applied electric signal.

However, because semiconductor devices are high-integrated, misalignment is frequently generated at an alignment process between a test needle and a test pattern. Accordingly, a wafer level test result becomes to inaccurate to reduce a test yield.

### SUMMARY

In an embodiment of the present invention, a misalignment detection apparatus includes: a test pad unit; a guard unit configured to surround the test pad unit, and formed to maintain a predetermined interval with the test pad unit; and a power supply unit configured to supply a predetermined voltage to the guard unit.

In an embodiment of the present invention, a misalignment detection apparatus includes: a test pad unit; first guard patterns formed in parallel with a long axis of the test pad unit, and disposed at one side and another side of the test pad unit with respect to the long axis of the test pad unit; second guard patterns formed in parallel with a short axis of the test pad unit, and disposed at one side and another side of the test pad unit with respect to the short axis of the test pad unit; and power supply units configured to supply mutually different voltages to the first guard patterns and second guard patterns, respectively, which are formed at said one sides and another sides of the test pad unit.

In an embodiment of the present invention, a misalignment detection apparatus includes: a test pad unit; a guard unit spaced by a predetermined distance from the test pad unit, and configured with a plurality of patterns which are formed to surround the test pad unit; and a power supply unit configured to supply the plurality of patterns of the guard unit with mutually different power voltages, respectively, wherein the misalignment detection apparatus is configured to detect whether misalignment is generated and a direction thereof by current detected by a probe card when the test pad unit of the guard unit and a needle of the probe card are misaligned.

In an embodiment of the present invention, a misalignment detection apparatus includes: a test pad unit; a guard unit located adjacent the test pad unit at a predetermined distance from the test pad unit; and a power supply unit configured to supply a predetermined voltage to the guard unit.

### BRIEF DESCRIPTION OF THE DRAWINGS

Features, aspects, and embodiments are described in conjunction with the attached drawings, in which:

FIG. 1 is a block diagram schematically illustrating the configuration of a misalignment detection apparatus according to an embodiment of the present invention;

FIG. 2 is a detailed circuit diagram illustrating the configuration of a misalignment detection apparatus according to an embodiment of the present invention;

FIG. 3 is an enlarged plane view of the test pad unit illustrated in FIG. 1;

FIG. 4 is a plane view illustrating the configuration of a test pad unit according to an embodiment of the present invention; and

FIGS. 5 to 7 are detailed circuit diagrams illustrating the configurations of misalignment detection apparatuses according to other embodiments of the present invention.

### DETAILED DESCRIPTION

Hereinafter, an apparatus for detecting misalignment of a test pad according to the present invention will be described below with reference to the accompanying drawings through various embodiments. Wherever possible, the same reference numbers will be used throughout the drawings to refer to the same or like parts.

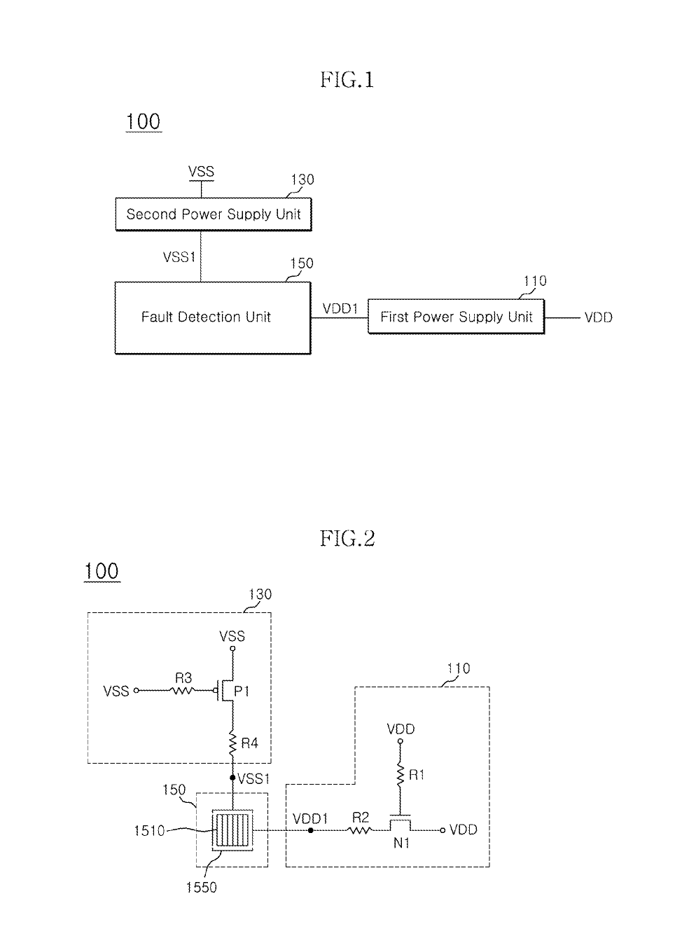

Referring to FIG. 1, an alignment fault detection apparatus 100 may include a first power supply unit 110, a second power supply unit 130, and a fault detection unit 150.

The first power supply unit 110 supplies the fault detection unit 150 with a first-level voltage VDD1 (hereinafter, referred to as a “first power voltage”), and the second power supply unit 130 supplies the fault detection unit 150 with a second-level voltage VSS1 (hereinafter, referred to as a “second power voltage”) which is different from the first-level voltage.

The fault detection unit 150 receives the first and second power voltages VDD1 and VSS1 from the first and second power supply units 110 and 130, respectively, and checks whether or not a needle (not shown) of a probe card and a test pad (not shown) are accurately aligned.

According to an embodiment of the present invention, the fault detection unit 150 can include a test pad unit, and can be configured to output current according to the first and second power voltages VDD1 and VSS1 when the needle of the probe card and the test pad are not accurately aligned.

In more detail (see FIG. 2) about the alignment fault detection apparatus 100 according to an embodiment of the present invention, the first power supply unit 110 can be configured to include a first switching element N1, a first resistor R1, and a second resistor R2. The first switching element N1 can be configured with, for example, an NMOS transistor, each of the gate and drain of which is electrically coupled to a first power terminal VDD corresponding to a high level, so that the first switching element N1 is maintained in a turn-on state. The first resistor R1 is electrically coupled between the first power terminal VDD and the gate of the first switching element N1, and supplies a stable voltage to the first switching element N1. The second resistor R2 is electrically coupled between the first switching element N1 and the fault detection unit 150, and supplies a stabilized first power voltage VDD1 to the fault detection unit 150.

The second power supply unit 130 can be configured to include a second switching element P1, a third resistor R3, and a fourth resistor R4. The second switching element P1 can be configured with, for example, a PMOS transistor, each of the gate and source of which is electrically coupled to a second power terminal VSS corresponding to a low level, so that the second switching element P1 is also maintained in a turn-on state. The third resistor R3 is electrically coupled between the second power terminal VSS and the gate of the second switching element P1, and supplies a stable voltage to the second switching element P1. The fourth resistor R4 is electrically coupled between the second switching element P1 and the fault detection unit 150, and supplies a stabilized second power voltage VSS1 to the fault detection unit 150.

The fault detection unit 150 can include a test pad unit 1510 and a guard unit 1550. The fault detection unit 150 constituted by the test pad unit 1510 and the guard unit 1550 can be formed within a scribe line of a wafer and can be formed in a process of manufacturing a semiconductor device.

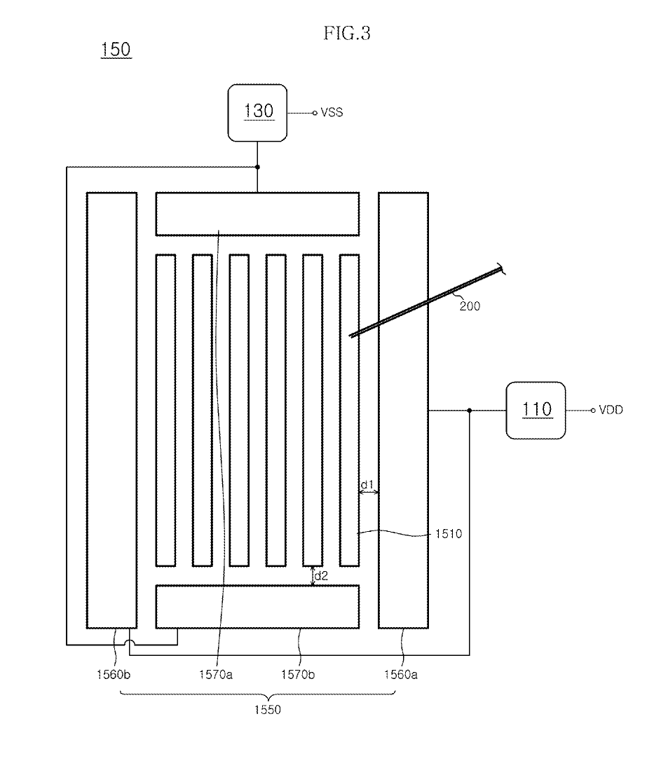

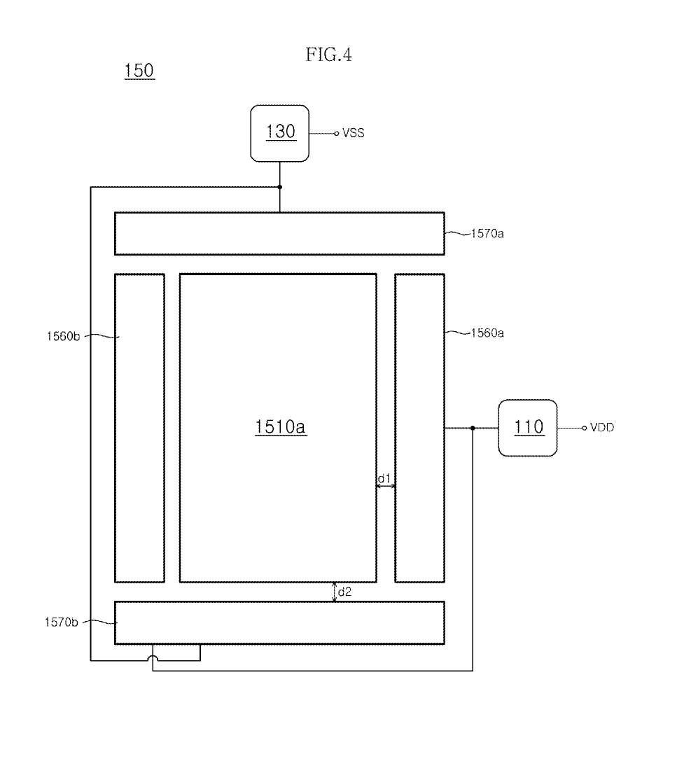

Referring to FIG. 3, the test pad unit 1510 can be configured to be a plurality of stripe patterns. The plurality of stripe patterns can be aligned in parallel to each other, and can be all configured as conductive patterns.

The guard unit 1550 can be disposed on an outside portion of the test pad unit 1510. The guard unit 1550 can have the shape of an actual ring surrounding the test pad unit 1510, or can include a pair of first guard patterns 1560a and 1560b and a pair of second guard patterns 1570a and 1570b. The pair of first guard patterns 1560a and 1560b can be disposed in substantially parallel to each other at a predetermined interval. The first guard patterns 1560a and 1560b can be extended in substantially parallel with a plurality of stripe patterns which constitute the test pad unit 1510. The pair of first guard patterns 1560a and 1560b are spaced apart by a first distance d1 from an outside of the test pad unit 1510, e.g. from the edge of the test pad unit 1510 (i.e. the end of a long axis of a stripe pattern). In addition, the first guard patterns 1560a and 1560b can be formed to have a length longer than those of the plurality of stripe patterns. The first guard patterns 1560a and 1560b can both be appropriately and electrically coupled with the first power supply unit 110, and the second guard patterns 1570a and 1570b can be appropriately and electrically coupled with the second power supply unit 130.

The pair of second guard patterns 1570a and 1570b can be disposed to be substantially perpendicular to the first guard patterns 1560a and 1560b. For example, the second guard patterns 1570a and 1570b can be disposed between the first guard patterns 1560a and 1560b which face each other. In addition, the second guard patterns 1570a and 1570b can be spaced by a second distance d2 from the edge portion of the test pad unit 1510 (i.e. from the end of a short axis of a stripe pattern). In this case, the first distance d1 and the second distance d2 can be, for example, equal to each other.

A wafer which has been subjected to a wafer level process is mounted on a probe test apparatus. Thereafter, a probe card of the probe test apparatus is aligned with a test pad of a wafer, and then a needle 200 of the probe card is contacted with a predetermined portion of the test pad unit 1510.

When the probe card and the test pad unit 1510 are normally aligned and contacted with each other, the probe test apparatus detects a voltage or current representing a floating state through the needle 200 of the probe card.

That is to say, the test pad unit 1510 is constituted by a plurality of stripe patterns configured as a conductive layer and is spaced from the first guard patterns 1560a and 1560b and second guard patterns 1570a and 1570b without an electrical connection, as described above, so that the test pad unit 1510 is maintained at a floating state. Therefore, when a normal alignment is achieved, the probe test apparatus detects a voltage or current suitable for the floating state.

However, when the probe card and the test pad unit 1510 are misaligned, the needle 200 of the probe card is contacted with the first guard patterns 1560a and 1560b or the second guard patterns 1570a and 1570b. In this case, since the first guard patterns 1560a and 1560b are coupled to the first power supply unit 110, and the second guard patterns 1570a and 1570b are coupled to the second power supply unit 130, the probe test apparatus detects a voltage or current corresponding to the first power voltage VDD or second power voltage VSS according to the contact position of the needle 200.

Therefore, with one test pad unit, a direction in which the overall probe test pads are aligned can be predicted by current detected by the probe test apparatus.

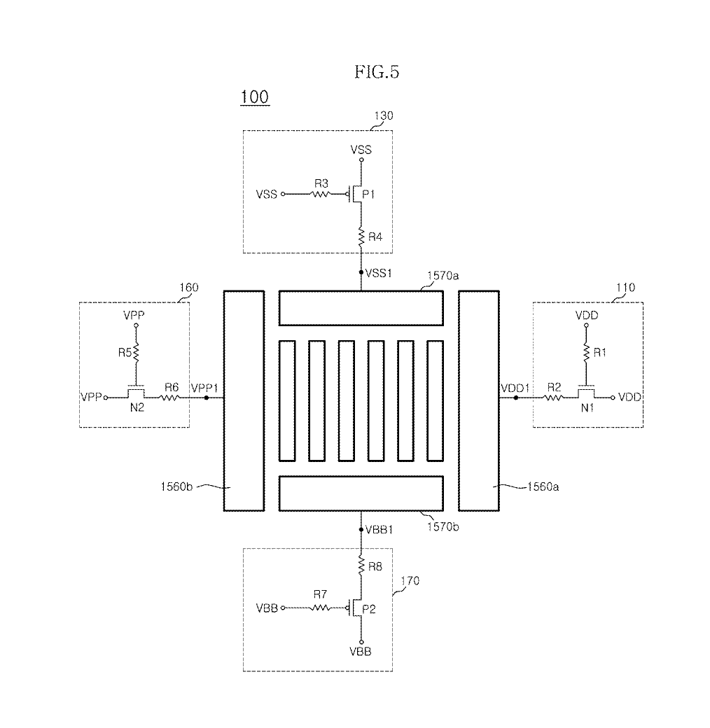

In this case, the fault detection unit 150 is not limited to the structure illustrated in FIG. 3, and a test pad unit 1510a can be configured in the shape of a plate, as illustrated in FIG. 4. In addition, first guard patterns 1560a and 1560b can be configured to have substantially the same length as that of the long axis of the test pad unit 1510a, and second guard patterns 1570a and 1570b can be configured to have a length to overlap all of the test pad unit 1510a and first guard patterns 1560a and 1560b.

Also, it is possible to supply different voltages to the pair of first guard patterns 1560a and 1560b and the pair of second guard patterns 1570a and 1570b, respectively.

That is to say, as illustrated in FIG. 5, one-side first guard pattern 1560a of the pair of first guard patterns 1560a and 1560b is electrically coupled to the first power supply unit 110 described above, and receives the first power voltage VDD1. The other-side first guard pattern 1560b can be electrically coupled to a third power supply unit 160 which supplies a third power voltage VPP1 having a level higher than that of the first power voltage VDD1. Similarly to the first power supply unit 110, the third power supply unit 160 can be constituted by a third switching element N2, a fifth resistor R5, and a sixth resistor R6. The third switching element N2 can be configured with an NMOS transistor, and the gate and drain of the third switching element N2 is electrically coupled to a third power terminal VPP corresponding to a high level. Accordingly, the third switching element N2 also is always turned on. In this case, since the third switching element N2 can be supplied with the third power voltage which is higher than the first power voltage, the third switching element N2 can be designed to have higher tolerance to a high voltage than the first switching element N1. In addition, the fifth resistor R5 is electrically coupled between the third power terminal VPP and the gate of the third switching element N2, and supplies a stable voltage to the third switching element N2. The sixth resistor R6 is electrically coupled between the third switching element N2 and the other-side first guard pattern 1560b of the fault detection unit 150, and supplies a stable third power voltage VPP1 to the other-side first guard pattern 1560b.

In addition, the one-side second guard pattern 1570a is supplied with the second power voltage VSS1 from the second power supply unit 130, and the other-side second guard pattern 1570b can be electrically coupled to a fourth power supply unit 170 which supplies a fourth power voltage VBB1 lower than the second power voltage VSS1.

The fourth power supply unit 170 can have a structure similar to that of the second power supply unit 130, and can include, for example, a fourth switching element P2, a seventh resistor R7, and an eighth resistor R8. The fourth switching element P2 can be configured with, for example, a PMOS transistor, each of the gate and source of which is electrically coupled to a fourth power terminal VBB corresponding to a substantial low level, so that the fourth switching element P2 also is always turned on. The seventh resistor R7 is electrically coupled between the fourth power terminal VBB and the gate of the fourth switching element P2, and supplies a stable voltage to the fourth switching element P2. The eighth resistor R8 also is electrically coupled between the fourth switching element P2 and the other-side second guard pattern 1570b, and supplies a stabilized fourth power voltage VBB1 to the other-side second guard pattern 1570b.

When the one-side first guard pattern 1560a, the other-side first guard pattern 1560b, the one-side second guard pattern 1570a, and the other-side second guard pattern 1570b are configured to receive mutually different voltages, as described above, current or voltages detected by the probe test apparatus become also different to each other when the needle 200 is misaligned. Accordingly, it is possible to accurately predict a direction, of up, down, left and right directions, in which misalignment is caused.

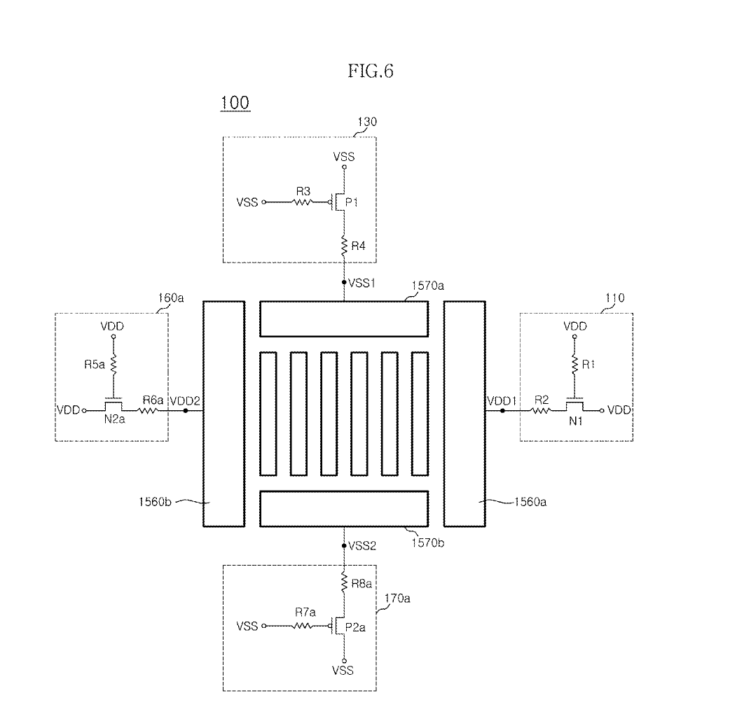

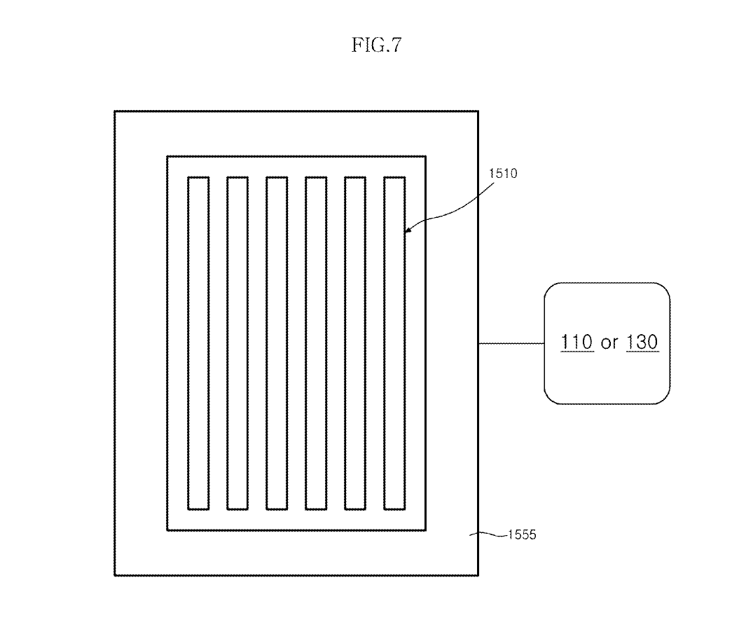

Also, as illustrated in FIG. 6, a third power supply unit 160a can be coupled to the first power voltage terminal VDD, instead of being coupled to the third power voltage terminal VPP (i.e., see FIG. 5), and can output a modified first power voltage VDD2 by adjusting the size of a third switching element N2a and the resistance values of fifth and sixth resistors R5a and R6a, which constitute the third power supply unit 160a. Since the modified first power voltage VDD2 has a level different from that of the first power voltage VDD1, the pair of first guard patterns 1560a and 1560b facing each other can be supplied with mutually different voltages.

Similarly, a fourth power supply unit 170a can be coupled to the second power voltage terminal VSS, instead of being coupled to the fourth power voltage terminal VBB (i.e., see FIG. 5), and can output a modified second power voltage VSS2 by adjusting the size of a fourth switching element P2a and the resistance values of seventh and eighth resistors R7a and R8a, which constitute the fourth power supply unit 170a. Since the modified second power voltage VSS2 has a level different from that of the second power voltage VSS1, the pair of second guard patterns 1570a and 1570b facing each other can be supplied with mutually different voltages.

In addition, as illustrated in FIG. 7, a guard unit 1555 can be configured in the shape of a ring without disconnection, wherein the guard unit 1555 can be electrically coupled to the first power supply unit 110 or the second power supply unit 130.

As described in detail above, according to the present invention, an alignment fault detection apparatus capable of detecting misalignment between the needle of a probe card and test pads is provided in a scribe line having the test pads mounted thereon. Accordingly, it is possible to easily predict not only whether or not misalignment is generated, but also the direction in which the misalignment is generated.

While various embodiments have been described above, it will be understood to those skilled in the art that the embodiments described are by way of example only. Accordingly, the apparatus described herein should not be limited based on the described embodiments.

What is claimed is:

1. A misalignment detection apparatus comprising:
a test pad unit;
a guard unit configured to surround the test pad unit, and formed to maintain a predetermined interval with the test pad unit; and
a power supply unit configured to supply a predetermined voltage to the guard unit.

2. The misalignment detection apparatus according to claim 1, wherein the test pad unit and the guard unit are formed within a scribe line of a wafer.

3. The misalignment detection apparatus according to claim 1, wherein the test pad unit is configured with a plurality of stripe patterns which extend in parallel with each other.

4. The misalignment detection apparatus according to claim 3, wherein the guard unit comprises:
a first guard pattern configured to surround one part of the test pad unit; and
a second guard pattern configured to surround the other part of the test pad unit.

5. The misalignment detection apparatus according to claim 4, wherein the first guard pattern is formed in parallel to a long axis of the test pad unit, and is disposed on one side and the other side of the test pad unit with respect to the long axis of the test pad unit.

6. The misalignment detection apparatus according to claim 5, wherein the second guard pattern is formed in parallel to a short axis of the test pad unit, and is disposed on one side and the other side of the test pad unit with respect to the short axis of the test pad unit.

7. The misalignment detection apparatus according to claim 4, wherein the power supply unit comprises:
a first power supply unit configured to supply the first guard pattern with a first power voltage; and
a second power supply unit configured to supply the second guard pattern with a second power voltage which is different from the first power voltage.

8. The misalignment detection apparatus according to claim 7, wherein the first power supply unit supplies a substantial high-level voltage to the first guard pattern, and the second power supply unit supplies a substantial low-level voltage to the second guard pattern.

9. The misalignment detection apparatus according to claim 8, wherein the first power supply unit comprises:
an NMOS transistor having the drain thereof electrically coupled to a first power terminal;
a first voltage drop resistor electrically coupled between the gate of the NMOS transistor and the first power terminal; and
a second voltage drop resistor electrically coupled between the source of the NMOS transistor and the first guard pattern.

10. The misalignment detection apparatus according to claim 8, wherein the second power supply unit comprises:
a PMOS transistor having the source thereof electrically coupled to a second power terminal;
a third voltage drop resistor electrically coupled between the is gate of the PMOS transistor and the second power terminal; and
a fourth voltage drop resistor electrically coupled between the drain of the PMOS transistor and the second guard pattern.

11. A misalignment detection apparatus comprising:
a test pad unit;
first guard patterns formed in parallel with a long axis of the test pad unit, and disposed at one side and another side of the test pad unit with respect to the long axis of the test pad unit;
second guard patterns formed in parallel with a short axis of the test pad unit, and disposed at one side and another side of the test pad unit with respect to the short axis of the test pad unit; and
power supply units configured to supply mutually different voltages to the first guard patterns and second guard patterns, respectively, which are formed at said one sides and another sides of the test pad unit.

12. The misalignment detection apparatus according to claim 11, wherein the test pad unit is configured with a plurality of stripe patterns which extend in parallel with each other.

13. The misalignment detection apparatus according to claim 11, wherein the power supply units comprises:
a first power supply unit configured to supply a first power voltage to the first guide pattern which is formed at one side with respect to the long axis of the test pad unit;
a second power supply unit configured to supply a second power voltage to the first guide pattern which is formed at another side with respect to the long axis of the test pad unit;
a third power supply unit configured to supply a third power voltage to the second guide pattern which is formed at one side with respect to the short axis of the test pad unit; and
a fourth power supply unit configured to supply a fourth power voltage to the second guide pattern which is formed at another side with respect to the short axis of the test pad unit.

14. The misalignment detection apparatus according to claim 13, wherein:
the first power supply unit includes a first power terminal;
the second power supply unit includes a second power terminal;
the third power supply unit includes a third power terminal;
the fourth power supply unit includes a fourth power terminal; and
the first, second, third, and fourth power terminals having mutually different voltages.

15. The misalignment detection apparatus according to claim 13, wherein:
the first power supply unit includes a first power terminal;
the second power supply unit includes a second power terminal;
the third power supply unit includes the first power terminal;
the fourth power supply unit includes the second power terminal; and
the first and second power terminals having different voltages.

16. The misalignment detection apparatus according to claim 13, wherein the first and third power voltages have a substantial high level, and the second and fourth power voltages have a substantial low level.

17. A misalignment detection apparatus comprising:
a test pad unit;
a guard unit spaced by a predetermined distance from the test pad unit, and configured with a plurality of patterns which are formed to surround the test pad unit; and
a power supply unit configured to supply the plurality of patterns of the guard unit with mutually different power voltages, respectively,
wherein the misalignment detection apparatus is configured to detect whether misalignment is generated and a direction thereof by current detected by a probe card when the test pad unit of the guard unit and a needle of the probe card are misaligned.

18. A misalignment detection apparatus comprising:
a test pad unit;
a guard unit located adjacent the test pad unit at a predetermined distance from the test pad unit; and
a power supply unit configured to supply a predetermined voltage to the guard unit.

19. The misalignment detection apparatus according to claim 18, wherein the guard unit forms a ring around the test pad unit.

20. The misalignment detection apparatus according to claim 18, wherein the power supply unit includes a first power supply unit and a second power supply unit, either of which configured to supply a power voltage different from the other to the guard unit.
